(19) United States
(12) Patent Application Publication
(10) Pub. No.: US 2026/0229452 A1
(43) Pub. Date: Aug. 6, 2026

(54) CHARGED PARTICLE BEAM DEVICE AND METHOD FOR CONTROLLING CHARGED PARTICLE BEAM DEVICE

(71) Applicant: HITACHI HIGH-TECH ANALYSIS CORPORATION, Tokyo (JP)

(72) Inventors: Shota TORIKAWA, Tokyo (JP); Tatsuya ASAHATA, Tokyo (JP)

(21) Appl. No.: 19/157,237

(22) PCT Filed: Feb. 16, 2023
(86) PCT No.: PCT/JP2023/005537

§ 371 Date: Aug. 15, 2025

(51) Int. Cl. H01J 37/302; H01J 37/20; H01J 37/305

(52) U.S. Cl. CPC H01J 37/3023; H01J 37/20; H01J 37/3053; H01J 2237/202; H01J 2237/3174

(57) ABSTRACT

A charged particle beam device includes a charged particle beam emission optical system, a sample stage, a driving mechanism that drives the sample stage, and a computer that sets a cross-section of the sample as a milling region of the sample and controls the charged particle beam emission optical system and the driving mechanism when performing slicing on the milling region.

### CROSS REFERENCE

The present Application for Patent is a 371 national phase filing of International Patent Application No. PCT/JP2023/005537 by TORIKAWA et al., entitled “CHARGED PARTICLE BEAM DEVICE AND METHOD FOR CONTROLLING CHARGED PARTICLE BEAM DEVICE,” filed Feb. 16, 2023, assigned to the assignee hereof, and is expressly incorporated by reference in its entirety herein.

### Technical Field

The present disclosure relates to a charged particle beam device and a method for controlling the charged particle beam device.

### BACKGROUND ART

After a cross-section of a sample is formed using a charged particle beam device, milling that is performed at regular intervals toward the depth direction of the cross-section is referred to as slicing. Slicing is mainly performed by emitting a charged particle beam toward the cross-section of a sample, and the emission amount of the charged particle beam for processing at each interval is always constant.

In relation to slicing, a technique capable of achieving high-precision milling pitch over a wide area is known (see, for example, Patent Document 1). This technique synchronizes two or more types of FIB deflection control, namely high-precision scanning with a fine deflection amount and image shift with a large deflection amount, thereby scanning a wide area with high density in comparison to existing techniques. Further, image shift of an SEM is made to follow a position milled using image shift of an FIB. For a single milled cross-section, a plurality of SEM images is acquired and the images are stitched together, thereby creating a high-precision image.

Further, regarding the interval of slicing, a method of numerically setting the interval of slicing and a method of setting the diameter size of charged particle beam used for slicing are known. When the interval of slicing is numerically set, the slicing is performed at the set interval. When the set value is larger than the diameter of a charged particle beam, slicing at each interval is performed using raster scan. When the diameter size of a charged particle beam is set, the milling interval is determined on the basis of the set diameter size, and slicing is performed at the determined milling interval.

Meanwhile, when an analysis target such as a semiconductor device is analyzed using a charged particle beam device, a charged particle beam is emitted such that parallel cross-sections of the structure can be formed. In recent semiconductor devices, the structure is becoming more three-dimensional, and the area that requires high parallelism in the structure to be analyzed is increasing.

### RELATED ART DOCUMENT

### Patent Document

Patent Document 1: Japanese Patent Application Publication No. 2013-089431

### DISCLOSURE

### Technical Problem

In general, since a charged particle beam has a characteristic current density distribution, the parallelism of the cross-section with respect to the emission direction of the charged particle beam is lower than the parallelism of the cross-section with respect to the scanning direction. Accordingly, it has been common to perform milling by aligning the scanning direction, in which high cross-sectional parallelism is obtained, with the longitudinal direction of the structure to be analyzed (excluding cases in which the structure is sliced in a circular manner).

However, as the structure of semiconductor devices becomes more three-dimensional, it is becoming necessary to increase the parallelism with respect to the emission direction of a charged particle beam.

The present disclosure has been devised in view of the points described above, and an objective of the present disclosure is to provide a charged particle beam device that can improve the milling parallelism with respect to the emission direction of a charged particle beam, and a method for controlling the charged particle beam device.

### Technical Solution

In order to solve the above problems and achieve the related objectives, the present disclosure employed the following form.
(1) A charged particle beam device according to an aspect of the present disclosure is a charged particle beam device that mills a sample. The charged particle beam device includes: a charged particle beam emission optical system configured to emit a charged particle beam; a sample stage configured to hold a sample; a driving mechanism configured to drive the sample stage; and a computer configured to set a cross-section of the sample in a milling region of the sample and control the charged particle beam emission optical system and the driving mechanism when performing slicing on the set milling region, wherein the computer controls the driving mechanism on the basis of information specifying an angle formed by an irradiation surface of the sample and an irradiation axis of the charged particle beam, sets the angle formed by the irradiation surface and the irradiation axis, sets respective regions to be irradiated by a plurality of charged particle beams emitted in a predetermined direction of the milling region, when performing slicing on the milling region of the sample, and controls the charged particle beam emission optical system and the driving mechanism to perform slicing by scanning the milling region with the charged particle beam while maintaining the set angle.
(2) In the charged particle beam device described in (1), the computer sets positions where the plurality of charged particle beams emitted in the predetermined direction of the milling region overlaps, respectively, as irradiation positions.
(3) In the charged particle beam device described in (1) or (2), the computer sets the overlap of the plurality of charged particle beams emitted in the predetermined direction to 50% or more and 95% or less of a diameter of the charged particle beams.
(4) In the charged particle beam device described in any one of (1) to (3), the computer sets a time interval for emitting the plurality of charged particle beams to 100 microseconds or less.
(5) In the charged particle beam device described in any one of (1) to (4), the computer sets an angle formed by the irradiation surface of the sample and the irradiation axis of the charged particle beam to 0.5 degrees or more.
(6) In the charged particle beam device described in any one of (1) to (5), the computer changes the milling region in the same direction as a milling progress direction of the irradiation surface in the milling region of the sample, and sets a change amount of the milling region to be equal to a milling progress amount of the irradiation surface.
(7) In the charged particle beam device described in any one of (1) to (6), Further, the computer sets a change of the milling region to a position where milling regions before and after the change overlap.
(8) In the charged particle beam device described in any one of (1) to (7), the computer sets a change amount of the milling region to be 50% or more and 95% or less of a diameter of the charged particle beam.
(9) In the charged particle beam device described in any one of (1) to (8), the computer sets a change amount of the milling region to be equal to intervals of the plurality of charged particle beam.
(10) A method for controlling a charged particle beam device according to an aspect of the present disclosure is a method for controlling a charged particle beam device that includes a charged particle beam emission optical system configured to emit a charged particle beam, a sample stage configured to hold a sample, a driving mechanism configured to drive the sample stage, a computer configured to set a cross-section of the sample in a milling region of the sample and control the charged particle beam emission optical system and the driving mechanism when performing slicing on the set milling region. The method includes: a step in which the computer controls the driving mechanism on the basis of information specifying an angle formed by an irradiation surface of the sample and an irradiation axis of the charged particle beam, thereby setting the angle formed by the irradiation surface and the irradiation axis; a step in which the computer sets respective regions to be irradiated by a plurality of charged particle beams emitted in a predetermined direction of the milling region, when performing slicing on the milling region of the sample; and a step in which the computer controls the charged particle beam emission optical system and the driving mechanism to perform slicing by scanning the milling region with the charged particle beam while maintaining the set angle.

### Advantageous Effects

According to the present disclosure, it is possible to improve the parallelism of milling with respect to the irradiation direction of a charged particle beam.

### DESCRIPTION OF DRAWINGS

FIG. 1 is a schematic configuration diagram illustrating a charged particle beam device according to an embodiment of the present disclosure.

FIG. 2 is a schematic configuration diagram illustrating an example of driving a stage of the charged particle beam device according to the present embodiment.

FIG. 3 is a diagram illustrating an example of positions toward which the charged particle beam device according to the present embodiment emits a charged particle beam.

FIG. 4 is a diagram illustrating an example of the charged particle beam that is emitted by the charged particle beam device according to the present embodiment.

FIG. 5 is a flowchart illustrating an example of a milling process sequence of the charged particle beam device according to the present embodiment.

### MODE FOR INVENTION

Hereafter, a charged particle beam device according to the present embodiment, and a method for controlling the charged particle beam device are described with reference to the drawings. The embodiments described below are merely examples, and embodiments to which the present disclosure is applied are not limited to the following embodiments.

Meanwhile, in all the drawings for explaining embodiments, components having the same function are denoted by the same reference numerals, and repeated explanations will be omitted.

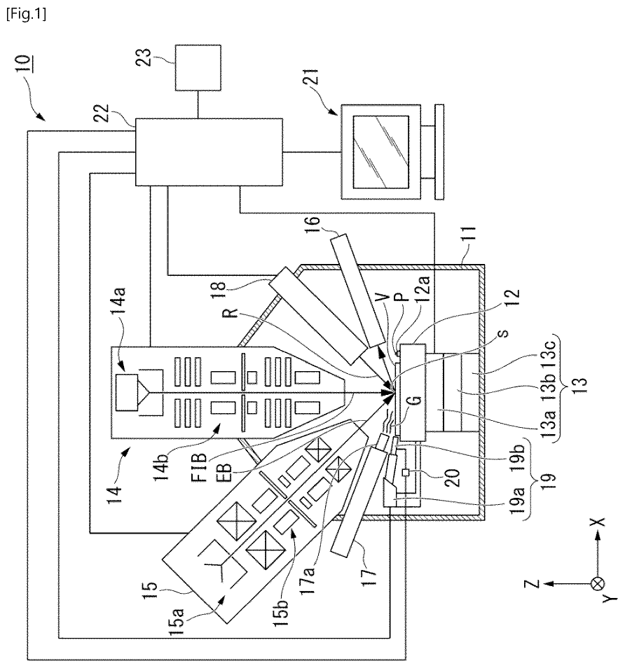

FIG. 1 is a schematic configuration diagram illustrating a charged particle beam device according to an embodiment of the present disclosure.

A charged particle beam device 10 according to an embodiment of the present disclosure performs slicing on a sample. The charged particle beam device 10 emits a charged particle beam. The charged particle beam device 10 includes a charged particle beam emission optical system that emits a charged particle beam, a sample stage that holds a sample, a driving mechanism that drives the sample stage, and a computer that sets a cross-section of the sample in a milling region of the sample and controls the charged particle beam emission optical system and the driving mechanism when performing slicing on the set milling region.

The computer controls the driving mechanism on the basis of information specifying an angle formed by an irradiation surface of a sample and an irradiation axis of the charged particle beam, and sets the angle formed by the irradiation surface and the irradiation axis. The computer sets respective regions to be irradiated by a plurality of charged particle beams emitted in a predetermined direction of a milling region of the sample, when performing slicing of the milling region of a sample. The computer controls the charged particle beam emission optical system and the driving mechanism to perform slicing by scanning a milling region with a charged particle beam while maintaining a set angle.

Specifically, as shown in FIG. 1, the charged particle beam device 10 includes a sample chamber 11 capable of maintaining its interior in a vacuum state, a stage 12, on which a sample piece holder P for holding a bulk sample V or a sample piece S can be fixed, in the sample chamber 11, and a stage driving mechanism 13 that drives the stage 12.

The charged particle beam device 10 includes a focused ion beam emission optical system 14 that emits a charged particle beam, such as a focused ion beam (FIB), toward an irradiation target in a predetermined irradiation region (i.e., a scanning range) in the sample chamber 11.

The charged particle beam device 10 includes an electron beam emission optical system 15 that emits an electron beam (EB) toward an irradiation target in a predetermined irradiation region in the sample chamber 11.

The charged particle beam device 10 includes a detector 16 that detects secondary charged particles (secondary electrons and secondary ions) R generated from an irradiation target by emission of a charged particle beam or an electron beam.

The charged particle beam device 10 includes a gaseous ion beam emission optical system 18 that emits a gaseous ion beam (GB) toward an irradiation target in a predetermined irradiation region in the sample chamber 11.

The focused ion beam emission optical system 14, the electron beam emission optical system 15, and the gaseous ion beam emission optical system 18 are arranged such that their respective beam emission axes can intersect at substantially one point on the stage 12. That is, when the sample chamber 11 is viewed from the side in a plan view, the focused ion beam emission optical system 14 is disposed in the vertical direction, and the electron beam emission optical system 15 and the gaseous ion beam emission optical system 18 are each disposed a direction inclined, for example, at 45 degrees with respect to the vertical direction.

By this layout, when the sample chamber 11 is viewed from the side in a plan view, the beam emission axis of the gaseous ion beam GB is, for example, in a direction that intersects perpendicularly with the beam emission axis of the electron beam EB emitted from the electron beam emission optical system 15.

The charged particle beam device 10 includes a gas supply unit 17 that supplies gas G to the surface of an irradiation target. An example of the gas supply unit 17 is, specifically, a nozzle 17a having an outer diameter of approximately 200 μm.

The charged particle beam device 10 includes: a sample piece transfer unit 19 composed of a needle 19a that extracts a sample piece S from a sample V fixed on the stage 12 and holds and transfers the sample piece S to a sample piece holder P, and a needle driving mechanism 19b that transports the sample pieces S by driving the needle 19a; and an absorption current detector 20 detecting an incoming current (also referred to as absorption current) of the charged particle beam flowing into the needle 19a, wherein an incoming current signal is sent to a computer for image generation.

The charged particle beam device 10 includes a display device 21 that displays image data, etc. on the basis of secondary charged particles R detected by the detector 16, a computer 22, and an input device 23.

The irradiation targets of the focused ion beam emission optical system 14 and the electron beam emission optical system 15 include the sample V fixed on the stage 12, the sample piece S, and the needle 19a or the sample piece holder P located in an irradiation region.

The charged particle beam device 10 can perform, on an irradiation portion, imaging or various types of milling (excavation, trimming, etc.) by sputtering, and etching, slicing, and forming of a deposition film by scanning a charged particle beam over the surface of an irradiation portion, such as a sample.

The charged particle beam device 10 can perform milling for cutting a sample piece S from a sample V, and forming a micro sample piece Q for observation using a transmission electron microscope (TEM) or an analysis sample piece for electron beam analysis from the cut sample piece S. An example of the micro sample piece Q includes a thin-plate sample and a needle-shaped sample.

The charged particle beam device 10 can obtain a micro sample piece Q for observation by thinning, for example, the tip portion of the sample piece S moved to the sample piece holder P to a desired thickness (e.g., 5 nm to 100 nm) suitable for transmission observation using a transmission electron microscope. The charged particle beam device 10 can perform surface observation of irradiation targets such as the sample piece S and the needle 19a by scanning a charged particle beam or an electron beam over the surfaces of the irradiation targets.

The absorption current detector 20 includes a preamplifier and amplifies the incoming current of the needle and sends it to the computer 22. A needle-shaped absorption current image can be displayed on the display device 21 on the basis of the needle incoming current detected by the absorption current detector 20 and a signal synchronized with scanning of a charged particle beam, so that the shape or tip position of the needle can be identified.

The sample chamber 11 is configured to be evacuated to a desired vacuum state by an evacuation unit (not shown) and to maintain the desired vacuum state.

The stage 12 holds the sample V. The sample stage 12 includes a holder mount 12a that holds the sample piece holder P. The holder mount 12a may have a structure on which a plurality of sample piece holders P can be mounted.

The stage driving mechanism 13 is accommodated in the sample chamber 11 while being connected to the stage 12, and displaces the stage 12 with respect to a predetermined axis in accordance with a control signal output from the computer 22.

The stage driving mechanism 13 includes a moving unit 13a that moves the stage 12 in parallel along at least an X-axis and a Y-axis, which are parallel to a horizontal plane and orthogonal to each other, and a Z-axis, which is oriented in a vertical direction and orthogonal to both the X-axis and the Y-axis. The stage driving mechanism 13 includes a tilting actuator 13b that tilts the stage 12 about the X-axis or the Y-axis, and a rotating actuator 13c that rotates the stage 12 about the Z-axis.

The focused ion beam emission optical system 14 is fixed to the sample chamber 11 such that a beam emission part (not shown) is directed toward the stage 12 from a position above the stage 12 in the vertical direction within an irradiation region in the sample chamber 11 and such that the optical axis is parallel to the vertical direction. Accordingly, a charged particle beam can be emitted downward from above in the vertical direction toward irradiation targets such as the sample V and the sample piece S mounted on the stage 12, and the needle 19a located within the irradiation region.

Further, the charged particle beam device 10 may include an ion beam emission optical system other than the focused ion beam emission optical system 14 described above.

The ion beam emission optical system is not limited to an optical system that forms a charged particle beam as described above. For example, the ion beam emission optical system may be a projection-type ion beam emission optical system that has a stencil mask having an opening of a predetermined shape and installed therein and that forms a shaped beam having the shape of the opening of the stencil mask. According to such a projection-type ion beam emission optical system, a shaped beam having a shape corresponding to a milling region around the sample piece S can be precisely formed, whereby the milling time is shortened.

The focused ion beam emission optical system 14 includes an ion source 14a that generates ions and an ion optical system 14b that focuses and deflects ions extracted from the ion source 14a. The ion source 14a and the ion optical system 14b are controlled in accordance with control signals output from the computer 22, and the irradiation position and emission condition of the charged particle beam are controlled by the computer 22.

The ion source 14a is, for example, a liquid metal ion source using liquid gallium, a plasma-type ion source, or a gas field ionization ion source. The ion optical system 14b has, for example, a first electrostatic lens such as a condenser lens, and a second electrostatic lens such as an electrostatic deflector and an objective lens.

When a plasma-type ion source is used as the ion source 14a, high-speed milling by means of a large-current beam can be achieved, so it is suitable for cutting out a large-sized sample piece S. For example, by using argon ions for a gas field ionization ion source, it is also possible to emit an argon ion beam from the focused ion beam emission optical system 14.

The electron beam emission optical system 15 is fixed to the sample chamber 11 such that a beam emission part (not shown) is directed toward the stage 12 in an inclined direction tilted at a predetermined angle (for example, 60 degrees) with respect to the vertical direction of the stage 12 within an irradiation region in the sample chamber 11 and such that the optical axis is parallel to the inclined direction. Accordingly, a charged particle beam can be emitted downward from above in the inclined direction toward irradiation targets such as the sample V and the sample piece S fixed on the stage 12, and the needle 19a located within the irradiation region.

The electron beam emission optical system 15b includes an electron source 15a that generates electrons and an electron optical system 15b that converges and deflects electrons emitted from the electron source 15a. The electron source 15a and the electron optical system 15b are controlled in accordance with control signals output from the computer 22, and the irradiation position and emission condition of the electron beam are controlled by the computer 22. The electron optical system 15b includes, for example, an electron lens or a deflector.

Further, it is also acceptable to arrange the electron beam emission optical system 15 in the vertical direction and the focused ion beam emission optical system 14 in an inclined direction at a predetermined angle with respect to the vertical direction by switching the electron beam emission optical system 15 and the focused ion beam emission optical system 14.

The gaseous ion beam emission optical system 18 emits, for example, a gaseous ion beam GB such as an argon ion beam. The gaseous ion beam emission optical system 18 can emit argon gas with a low acceleration voltage of about 1 kV by ionizing the argon gas. Since such a gaseous ion beam GB has lower convergence than a focused ion beam FIB, the etching rate for the sample piece S or the micro sample piece Q is reduced. Therefore, it is suitable for precise finishing milling of the sample piece S or the micro sample piece Q.

The detector 16 detects the intensity of secondary charged particles (secondary electrons and secondary ions) R (i.e., the amount of secondary charged particles) emitted from an irradiation target such as the sample V, the sample piece S, and the needle 19a when a charged particle beam or an electron beam is emitted toward the irradiation target, and outputs information of the detected amount of the secondary charged particles R. The detector 16 is disposed at a position inside the sample chamber 11 where it can detect the amount of the secondary charged particles R, for example, at an upward position inclined with respect to an irradiation target such as the sample V or the sample piece S in an irradiation region, and is fixed to the sample chamber 11.

The gas supply unit 17 is fixed to the sample chamber 11, has a gas injection part (also referred to as a nozzle) inside the sample chamber 11, and is disposed to face the stage 12. The gas supply unit 17 can supply an etching gas for selectively promoting etching of the sample V and the sample piece S by a charged particle beam (focused ion beam) in accordance with the materials, and a deposition gas for forming a deposition film on the surface of the sample V and the sample piece S by a deposit such as a metal or an insulator, to the sample V and the sample piece S.

The needle driving unit 19b, which constitutes the sample piece transfer unit 19, is accommodated inside the sample chamber 11 in a state in which the needle 19a is connected, and displaces the needle 19a according to a control signal output from the computer 22.

The needle driving mechanism 19b is integrally installed with the stage 12, and, for example, when the stage 12 is rotated about a tilt axis (i.e., the X-axis or the Y-axis) by the tilting actuator 13b, it is moved integrally with the stage 12.

The needle driving mechanism 19b includes a moving actuator (not shown) for moving the needle 19a in parallel along each of the three-dimensional coordinate axes, and a rotating actuator (not shown) for rotating the needle 19a about a central axis of the needle 19a.

Meanwhile, the three-dimensional coordinate axes are independent from an orthogonal three-axis coordinate system of the sample stage, and, in an orthogonal three-axis coordinate system having two-dimensional coordinate axes parallel to the surface of the stage 12, when the surface of the stage 12 is in a tilted state or a rotated state, the coordinate system is inclined and rotated.

The computer 22 is disposed outside the sample chamber 11. The computer 22 is connected with a display device 21 and an input device 23 such as a mouse or a keyboard for outputting a signal according to an input operation by an operator. The computer 22 integrally controls operations of the charged particle beam device 10 on the basis of a signal output from the input device 23 or a signal generated by preset automatic operation control processing.

The computer 22 controls at least the stage driving mechanism 13, the focused ion beam emission optical system 14, the electron beam emission optical system 15, the gas supply unit 17, and the needle driving mechanism 19b.

The computer 22 receives information specifying an angle formed by an irradiation surface of a sample and an irradiation axis of a charged particle beam (hereinafter referred to as “tilt angle θa”). The information specifying the tilt angle θa of the sample may be output from the input device 23 connected to the computer 22.

The computer 22 controls the stage driving mechanism 13 on the basis of the received information specifying the tilt angle θa of the sample such that the irradiation surface and the irradiation axis form the tilt angle θa. An example of the tilt angle θa is 0.5 degrees or more, and more preferably, 1.1 degrees or more.

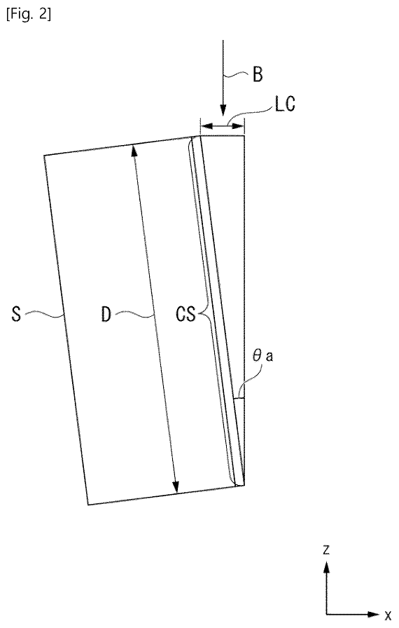

FIG. 2 is a schematic configuration diagram illustrating an example of driving a stage of the charged particle beam device according to the present embodiment. In FIG. 2, D is a length in a direction perpendicular to a scanning direction of a charged particle beam to an observation surface CS of the sample S. LC is a length in a direction perpendicular to the scanning direction of the charged particle beam in the surface of the sample S.

The computer 22 generates a control signal for causing the stage driving mechanism 13 to drive the stage 12, on the basis of information specifying the tilt angle θa. The computer 22 outputs the generated control signal to the stage driving mechanism 13.

The stage driving mechanism 13 drives the stage 12 on the basis of a control signal output from the computer 22. Specifically, the stage driving mechanism 13 performs control such that the irradiation surface (observation surface CS) of the sample S and the irradiation axis of the charged particle beam B form the tilt angle θa.

As a result, the charged particle beam device 10 enables observation of the observation surface CS of the cross-section through the length LC in a direction perpendicular to the scanning direction of the charged particle beam by emitting the charged particle beam B toward the observation surface CS. The length LC in the direction perpendicular to the scanning direction of the charged particle beam is longer than the size of the sample S. Returning to FIG. 1, the description is continued.

The computer 22 sets a milling region on an irradiation surface of the sample S. An example of the milling region is a predetermined region of an observation surface of a cross-section of the sample S.

The computer 22 derives a beam diameter of the charged particle beam emitted by the focused ion beam emission optical system 14. Here, the computer 22 derives a beam diameter corresponding to each irradiation region of the charged particle beam on the irradiation surface. An example of the beam diameter is represented by Equation (1).

$${D = [ {( 2 M \times R s )}^{2} + {\{ ( 1 / 2 ) \times Csi \times a {i}^{3} \}}^{2} + {( C c i \times a i \times Δ V / V )}^{2} )}^{0.5} \qquad ( 1 )$$

In Equation (1), D is a beam diameter, M is an optical system magnification, Rs is a source radius, Csi is a spherical aberration coefficient, ai is an image-plane opening half-angle, Cci is a chromatic aberration coefficient, ΔV is an energy spread, and V is an acceleration energy.

The computer 22 sets a plurality of irradiation positions of the charged particle beam on the basis of the derived beam diameter D of the charged particle beam. An example of the plurality of irradiation positions of the charged particle beam is the interval between adjacent irradiation positions of the charged particle beam.

The computer 22 generates a control signal for causing the focused ion beam emission optical system 14 and the stage driving mechanism 13 to emit the charged particle beam toward each of the plurality of irradiation positions, on the basis of information specifying the plurality of irradiation positions of the charged particle beam.

The computer 22 outputs a control signal to the focused ion beam emission optical system 14 and the stage driving mechanism 13.

The focused ion beam emission optical system 14 acquires the control signal output from the computer 22. The focused ion beam emission optical system 14 controls inputs to a lens electrode and a scanning electrode of the focused ion beam emission optical system 14, on the basis of the acquired control signal, thereby controlling an irradiation position, a beam diameter, and an irradiation amount of the charged particle beam emitted by the focused ion beam emission optical system 14.

The stage driving mechanism 13 acquires a control signal output from the computer 22, and, on the basis of the acquired control signal, controls an irradiation position of the charged particle beam emitted by the focused ion beam emission optical system 14 by displacing the stage 12 with respect to a predetermined axis.

The computer 22 generates a control signal for changing the milling region in the same direction as a milling progress direction of the irradiation surface in the milling region of the sample S, and for setting a change amount of the milling region to be equal to a milling progress amount of the irradiation surface. Here, the computer 22 sets the change of the milling region to a position where the milling regions before and after the change overlap. The computer 22 sets the change amount of the milling region to be 50% or more and 95% or less of the diameter of the charged particle beam.

The computer 22 outputs a control signal to the focused ion beam emission optical system 14 and the stage driving mechanism 13.

The focused ion beam emission optical system 14 acquires the control signal output from the computer 22. The focused ion beam emission optical system 14 controls inputs to a lens electrode and a scanning electrode of the focused ion beam emission optical system 14, on the basis of the acquired control signal, thereby controlling an irradiation position, a beam diameter, and an irradiation amount of the charged particle beam emitted by the focused ion beam emission optical system 14.

The stage driving mechanism 13 acquires a control signal output from the computer 22, and, on the basis of the acquired control signal, controls an irradiation position of the charged particle beam emitted by the focused ion beam emission optical system 14 by displacing the stage 12 with respect to a predetermined axis.

The computer 22 converts a detected amount of secondary charged particles R detected by the detector 16 into a luminance signal corresponding to an irradiation position of the charged particle beam while scanning the irradiation position, thereby generating image data representing the shape of the irradiation target on the basis of a two-dimensional position distribution of the detected amount of the secondary charged particles R.

The computer 22 causes the display device 21 to display, together with each generated piece of image data, a screen for executing operations such as enlargement, reduction, movement, and rotation of the image data. The computer 22 causes the display device 21 to display a screen for performing various settings such as mode selection and milling setting in automatic sequence control.

A method of milling a sample using the charged particle beam device 10 having the configuration described above is described.

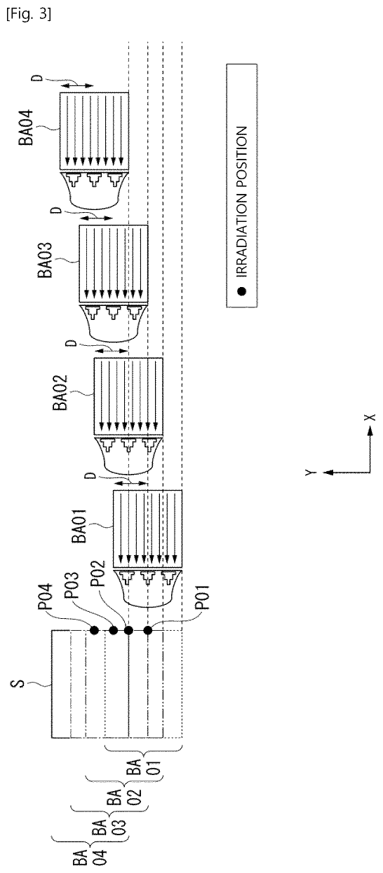

FIG. 3 is a diagram illustrating an example of positions toward which the charged particle beam device according to the present embodiment emits a charged particle beam. In FIG. 3, a sample piece S and charged particle beams are schematically illustrated.

Each of “BA01” to “BA04” represents a frame for scanning charged particle beams (the arrow in each frame indicates the scanning direction). Further, each of “BA01” to “BA04” also represents an irradiation area of each of charged particle beams “BA01” to “BA04” on the sample piece S.

Any frame among “BA01” to “BA04” is referred to as “BA.”

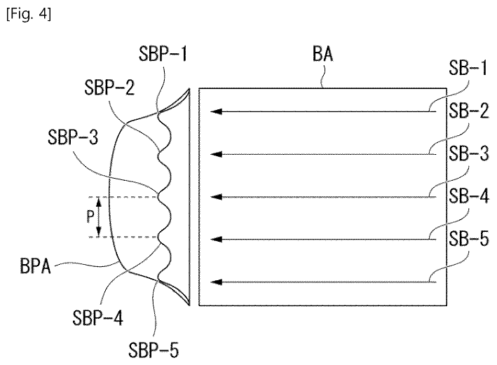

FIG. 4 is a diagram illustrating an example of the charged particle beam that is emitted by the charged particle beam device according to the present embodiment. The charged particle beam BA emitted toward an irradiation area BA of a charged particle beam includes a plurality of charged particle beams (hereinafter referred to as “one-line scan beams”). In the example shown in FIG. 4, the charged particle beam BA includes a charged particle sub-beam SB-1, a charged particle sub-beam SB-2, a charged particle sub-beam SB-3, a charged particle sub-beam SB-4, and a charged particle sub-beam SB-5.

The charged particle sub-beam SB-1 has a sub-beam profile SBP-1, the charged particle sub-beam SB-2 has a sub-beam profile SBP-2, the charged particle sub-beam SB-3 has a sub-beam profile SBP-3, the charged particle sub-beam SB-4 has a sub-beam profile SBP-4, and the charged particle sub-beam SB-5 has a sub-beam profile SBP-5. The pitch P between adjacent sub-beam profiles is equal to or less than the beam diameter of the sub-beams, is preferably 5% or more and 50% or less of the beam diameter, and is more preferably set to 10% or more and 30% or less. In other words, it is preferable that the sub-beams overlap each other, and the overlap of sub-beams is set to 50% or more and 95% or less, more preferably 70% or more and 90% or less.

The charged particle beam BA has a beam profile BPA including the sub-beam profile SBP-1, the sub-beam profile SBP-2, the sub-beam profile SBP-3, the sub-beam profile SBP-4, and the sub-beam profile SBP-5. The beam profile BPA of the charged particle beam BA becomes broad because it includes the sub-beam profile SBP-1, the sub-beam profile SBP-2, the sub-beam profile SBP-3, the sub-beam profile SBP-4, and the sub-beam profile SBP-5. The peak of the beam profile BPA is preferably flat rather than waveform-shaped, and the spacing of the sub-beams is set to achieve a desired profile. Returning to FIG. 3, the description is continued.

The focused ion beam emission optical system 14 forms a hole in a sample with a charged particle beam to expose a cross-section. This hole is used as an electron beam path for observation by a scanning electron microscope (SEM). The computer 22 sets the exposed cross-section in a milling region.

The computer 22 derives a beam diameter D of the charged particle beam BA, and, on the basis of the derived beam diameter D of the charged particle beam BA, sets a plurality of irradiation positions of the charged particle beam BA. An example of the plurality of irradiation positions of the charged particle beam BA is the interval between adjacent irradiation positions of the charged particle beam BA. Here, a case in which information specifying the interval between adjacent irradiation positions of the charged particle beam BA, which are a plurality of irradiation positions of the charged particle beam BA, is applied is further described.

The computer 22 sets irradiation positions such that irradiation regions of adjacent charged particle beams BA among a plurality of charged particle beams BA overlap, on the basis of the beam diameter D of the charged particle beam BA. Specifically, the computer 22 sets intervals of a plurality of charged particle beams emitted in the Y-axis direction to 5% or more and 50% or less, more preferably 10% or more and 30% or less of the beam diameter D of the charged particle beam. FIG. 3 illustrates a case in which an interval between adjacent charged particle beams among a plurality of charged particle beams emitted in the Y-axis direction is set to 25% of the beam diameter of the charged particle beam.

The focused ion beam emission optical system 14 performs slicing by sequentially emitting a charged particle beam B01, a charged particle beam B02, a charged particle beam B03, and a charged particle beam B04 toward an irradiation positions P01 (frame 1), an irradiation position P02 (frame 2), an irradiation position P03 (frame 3), and an irradiation position P04 (frame 4), respectively, in a set milling region (frame group).

The time interval for scanning emission in the frames is 100 microseconds or less. By setting the time interval for emitting the charged particle beam B to 100 microseconds or less, processing nonuniformity can be reduced compared to the case in which the time interval for emitting the charged particle beam B is longer than 100 microseconds.

After completion of the slicing, the new cross-section, also called an observation surface, produced by the slicing is captured by a SEM.

This is described in detail hereafter. The focused ion beam emission optical system 14 performs slicing on the irradiation region BA01 (frame 1) of the charged particle beam by emitting the charged particle beam BA01 toward the irradiation position P01 (frame 1) for scanning.

The focused ion beam emission optical system 14 performs slicing on the irradiation region BA02 (frame 2) of the charged particle beam by emitting the charged particle beam B02 toward the irradiation position P02 (frame 2) for scanning. An overlapping region exists between the irradiation region BA02 of the charged particle beam and the irradiation region BA01 of the charged particle beam.

Since the focused ion beam emission optical system 14 emits charged particles toward the irradiation position P02 having the region, where the irradiation region BA02 of the charged particle beam overlaps the irradiation region B01 of the previously emitted charged particle beam, it is possible to emit a beam toward an irradiation position where it is possible to appropriately obtain an edge effect. The overlapping irradiation region is subjected to slicing by both the charged particle beam emitted toward the irradiation position P01 and the charged particle beam emitted toward the irradiation position P02. Therefore, it is possible to maintain a desired slicing depth and flatten the profile of the milled surface.

Next, the focused ion beam emission optical system 14 performs slicing on the irradiation region BA03 of the charged particle beam by emitting the charged particle beam BA03 toward the irradiation position P03. An overlapping region exists between the irradiation region BA03 of the charged particle beam and the irradiation region BA02 of the charged particle beam.

Since the focused ion beam emission optical system 14 emits charged particles toward the irradiation position P03 having the region, where the irradiation region BA03 of the charged particle beam overlaps the irradiation region B02 of the previously emitted charged particle beam, it is possible to emit a beam toward an irradiation position where it is possible to appropriately obtain an edge effect. The overlapping irradiation region is subjected to slicing by both the charged particle beam emitted toward the irradiation position P02 and the charged particle beam emitted toward the irradiation position P03. Therefore, it is possible to maintain a desired slicing depth and flatten the profile of the milled surface.

Next, the focused ion beam emission optical system 14 performs slicing on the irradiation region BA04 of the charged particle beam by emitting the charged particle beam BA04 toward the irradiation position P04. An overlapping region exists between the irradiation region BA04 of the charged particle beam and the irradiation region BA03 of the charged particle beam.

Since the focused ion beam emission optical system 14 emits charged particles toward the irradiation position P04 having the region, where the irradiation region BA04 of the charged particle beam overlaps the irradiation region B03 of the previously emitted charged particle beam, it is possible to emit a beam toward an irradiation position where it is possible to appropriately obtain an edge effect. The overlapping irradiation region is subjected to slicing by both the charged particle beam emitted toward the irradiation position P03 and the charged particle beam emitted toward the irradiation position P04. Therefore, it is possible to maintain a desired slicing depth and flatten the profile of the milled surface.

As described above, the focused ion beam emission optical system 14 emits charged particles toward an irradiation position having a region, where an irradiation region of the charged particle beam overlaps an irradiation region of the previously emitted charged particle beam. Because the overlapping irradiation region is subjected to slicing by the charged particle beams emitted toward a plurality of irradiation positions, the parallelism of the slicing with respect to the emission direction of the charged particle beam can be improved.

Further, a beam diameter corresponding to each irradiation region of the charged particle beam on the irradiation surface is derived. Since the length of the cross-section viewed from the focused ion beam emission optical system 14 increases as the tilt angle becomes larger, slicing can be performed even when the tilt angle is increased by increasing the beam diameter of the charged particle beam.

The example shown in FIG. 3 describes a case in which four irradiation positions of the charged particle beam are set for the focused ion beam emission optical system 14, but the present disclosure is not limited to this example. For example, two to three irradiation positions or five or more irradiation positions may be set for the focused ion beam emission optical system 14.

In the example shown in FIG. 4, the case in which the charged particle beam BA includes a charged particle sub-beam SB-1, a charged particle sub-beam SB-2, a charged particle sub-beam SB-3, a charged particle sub-beam SB-4, and a charged particle sub-beam SB-5 was described, but the present disclosure is not limited thereto. The charged particle beam B includes two to four charged particle sub-beams or may include six or more charged particle sub-beams.

From the above, the focused ion beam emission optical system 14 emits charged particles toward an irradiation position having a region, where an irradiation region of the charged particle beam overlaps an irradiation region of the previously emitted charged particle beam, in the milling region of an irradiation surface that forms the tilt angle θa with the irradiation axis of the charged particle beam emitted by the focused ion beam emission optical system 14. Accordingly, it is possible to emit a charged particle beam toward irradiation positions where it is possible to always appropriately obtain an edge effect. Therefore, it is possible to maintain a desired slicing depth.

Next, the milling process sequence of the charged particle beam device 10 is described

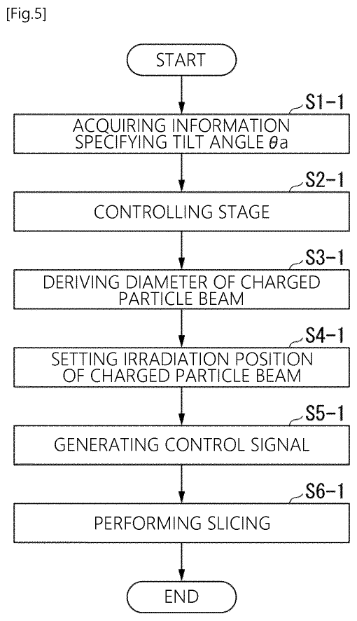

FIG. 5 is a flowchart illustrating an example of a milling process sequence of the charged particle beam device according to the present embodiment. Referring to FIG. 5, the operation after the focused ion beam emission optical system 14 forms a short hole to expose a cross-section by emitting a charged particle beam toward the sample and the computer 22 sets the exposed cross-section in a milling region is described.

### (Step S1-1)

In the charged particle beam device 10, the computer 22 acquires information specifying a tilt angle θa.

### (step S2-1)

In the charged particle beam device 10, the computer 22 generates a control signal for controlling the stage driving mechanism 13 such that an irradiation surface and an irradiation axis form the tilt angle θa, on the basis of the acquired information specifying the tilt angle θa. The computer 22 outputs the generated control signal to the stage driving mechanism 13. The stage driving mechanism 13 performs control such that the irradiation surface and the irradiation axis form the tilt angle θa by displacing the stage 12 with respect to a predetermined axis in accordance with the control signal output from the computer 22.

### (Step S3-1)

In the charged particle beam device 10, the computer 22 derives a beam diameter D of the charged particle beam emitted by the focused ion beam emission optical system 14.

### (Step S4-1)

In the charged particle beam device 10, the computer 22 derives a plurality of irradiation positions of the charged particle beam in the Y-axis direction on the basis of the derived beam diameter D of the charged particle beam, and sets the derived plurality of irradiation positions.

### (Step S5-1)

In the charged particle beam device 10, the computer 22 generates a control signal for causing the focused ion beam emission optical system 14 and the stage driving mechanism 13 to emit the charged particle beam toward each of the plurality of irradiation positions, on the basis of information specifying the plurality of irradiation positions of the charged particle beam.

### (Step S6-1)

In the charged particle beam device 10, the computer 22 outputs a control signal to the focused ion beam emission optical system 14 and the stage driving mechanism 13. The focused ion beam emission optical system 14 and the stage driving mechanism 13 acquire the control signal output from the computer 22 and perform slicing on the basis of the acquired control signal.

In the embodiment described above, although the case in which the charged particle beam device 10 derives a plurality of irradiation positions of a charged particle beam D on the basis of a beam diameter D of the charged particle beam emitted by the focused ion beam emission optical system 14 was described, the present disclosure is not limited thereto.

For example, the computer 22 may derive a plurality of irradiation positions of the charged particle beam D on the basis of an acceleration voltage. By changing the acceleration voltage, the profile of the charged particle beam changes. The computer 22 may also derive the interval between irradiation positions on the basis of the profile (shape) of the charged particle beam.

In the embodiment described above, the case in which the charged particle beam device 10 sets a plurality of irradiation positions of a charged particle beam in one direction such as the Y-axis direction of a sample was described, but the present disclosure is not limited to this example.

For example, the charged particle beam device 10 may set a plurality of irradiation positions of a charged particle beam in two directions such as the Z-axis direction and the Y-axis direction of a sample. When a plurality of irradiation positions of a charged particle beam is set in two directions, the intervals between adjacent charged particle beams among a plurality of charged particle beams may be made different in the two directions.

For example, the interval between adjacent charged particle beams among a plurality of charged particle beams emitted in the Z-axis direction and the interval between adjacent charged particle beams among a plurality of charged particle beams emitted in the Y-axis direction may be made different.

According to a charged particle beam device 10 of the present embodiment, the charged particle beam device that mills a sample includes a charged particle beam emission optical system that emits a charged particle beam as a focused ion beam emission optical system 14, a sample stage that holds a sample, a driving mechanism that drives the sample stage as a stage driving mechanism 13, and a computer 22 that sets a cross-section of the sample on a milling region of the sample and controls the charged particle beam emission optical system and the driving mechanism when performing slicing on the set milling region. The computer 22, on the basis of information specifying an angle formed by an irradiation surface of a sample and an irradiation axis of the charged particle beam, makes the driving mechanism perform control such that the irradiation surface and the irradiation axis form an angle; sets respective regions to be irradiated by a plurality of charged particle beams emitted in a predetermined direction of a milling region of the sample, when performing slicing on the milling region of the sample; and controls the charged particle beam emission optical system and the driving mechanism to perform slicing by scanning the milling region with a charged particle beam while maintaining the angle.

By configuring as described above, the charged particle beam device 10, on the basis of information specifying an angle formed by an irradiation surface of a sample and an irradiation axis of the charged particle beam, can make the driving mechanism perform control such that the irradiation surface and the irradiation axis form an angle, so it is possible to control the range that can be observed by FIB. The charged particle beam device 10 can set respective regions to be irradiated by a plurality of charged particle beams emitted in a predetermined direction of a milling region of the sample, when performing slicing on the milling region of the sample, so it is possible to mill the milling region.

Further, the computer 22 sets positions where a plurality of charged particle beams emitted in a predetermined direction of a milling region overlaps, respectively, as irradiation positions. By configuring as described above, compared to the case in which irradiation positions are set as positions where a plurality of charged particle beams emitted in a predetermined direction of a milling region does not overlap, it is possible to flatten the profile of a sliced surface.

Further, the computer 22 sets the overlap of a plurality of charged particle beams emitted in a predetermined direction to 50% or more and 95% or less of the diameter of the charged particle beams. By configuring as described above, the focused ion beam emission optical system 14 emits charged particles toward irradiation positions where an irradiation region of a charged particle beam overlaps an irradiation region of the previously emitted charged particle beam in a predetermined direction, so it is possible to emit a beam toward irradiation positions where it is possible to appropriately obtain an edge effect. When slicing is performed at intervals of 50% or more and 95% or less of the beam diameter of a charged particle beam, raster scanning is performed by overlapping irradiation regions of the charged particle beam by 50% or more and 95% or less during slicing at each interval.

Further, the computer 22 sets the time interval for emitting a plurality of charged particle beams to 100 microseconds or less. By configuring as described above, compared to the case in which the time interval for emitting plurality of charged particle beams is set to a time longer than 100 microseconds, the milling non-uniformity of a sliced surface can be reduced.

Further, the computer 22 sets the angle formed by an irradiation surface of a sample and the irradiation axis of a charged particle beam to 0.5 degrees or more. By configuring as described above, compared to the case in which the angle formed by an irradiation surface of a sample and the irradiation axis of a charged particle beam is set to less than 0.5 degrees, the etching rate of an irradiation surface of a sample can be made uniform regardless of position, so it is possible to flatten the profile of a milled surface. Further, the computer 22 changes a milling region in the same direction as a milling progress direction of an irradiation surface in a milling region of a sample, and sets a change amount of the milling region to be equal to a milling progress amount of the irradiation surface. By configuring as described above, since it is possible to change a milling region in the same direction as a milling progress direction of an irradiation surface, and set a change amount of the milling region to be equal to a milling progress amount of the irradiation surface, it is possible to emit a beam toward an irradiation position where it is possible to appropriately obtain an edge effect. Therefore, it is possible to maintain a desired slicing depth and flatten the profile of a milled surface.

Further, the computer 22 sets a change of a milling region to a position where the milling regions before and after the change overlap. By configuring as described above, since it is possible to set a change of a milling region to a position where the milling regions before and after the change overlap, the overlapping irradiation region is subjected to slicing by charged particle beams emitted toward a plurality of irradiation positions, respectively, whereby it is possible to improve the parallelism of slicing with respect to the emission direction of a charged particle beam.

Further, the computer 22 sets a change amount of a milling region to be 50% or more and 95% or less of the diameter of the charged particle beam. By configuring as described above, it is possible to perform slicing at intervals of 50% or more and 95% or less of the beam diameter of a charged particle beam, raster scanning is performed by overlapping irradiation regions of the charged particle beam by 50% or more and 95% or less during slicing at each interval. It is possible to emit a beam toward an irradiation position where it is possible to appropriately obtain an edge effect.

Further, the computer 22 sets a change amount of a milling region to match the pitch P between adjacent sub-beam profiles. Accordingly, it is possible to maintain consistent milling progress.

A program for realizing the control function of the computer 22 of the charged particle beam device 10 in the embodiment described above may be recorded on a computer-readable recording medium, and may be realized by reading and executing the program recorded on the recording medium by a computer system.

Meanwhile, the “computer system” stated herein is a computer system embedded in a charged particle beam device DI or a composite charged particle beam device D, including hardware such as an OS and peripheral devices.

Further, the term “computer-readable recording medium” refers to portable media such as flexible disks, optical magnetic disks, ROM, CD-ROM, and storage devices such as hard disks built in computer systems.

Further, the “computer-readable recording medium” may also include an object that temporarily and dynamically hold programs such as communication lines when programs are transmitted through networks like the Internet or communication lines such as telephone lines, and an object that holds programs for a certain period such as volatile memory inside a computer system serving as a server or client.

Further, the program may be for realizing a part of the functions described above, or may be realized by combining the function described above with a program already recorded in a computer system.

Further, a portion or the entirety of the computer 22 in the embodiment described above may be realized by an integrated circuit such as a Large Scale Integration (LSI). The functions of the computer 22 may be processed individually, or some or all of the functions may be integrated and processed.

Further, the method of circuit integration is not limited to LSI and may be realized by a dedicated circuit or a general-purpose processor. Further, when a technology for circuit integration that replaces LSI emerges due to advances in semiconductor technology, an integrated circuit by the technology may be used.

An embodiment of the present disclosure was described above in detail with reference to the drawings, but the specific configuration is not limited to the above description and various design changes may be made without departing from the scope of the present disclosure.

### DESCRIPTION OF REFERENCE NUMERALS

10: charged particle beam device
11: sample echamber
12: stage (sample stage)
13: stage driving mechanism
14: focused ion beam emission optical system
15: electron beam emission optical system
16: detector
17: gas supply unit
18: gaseous ion beam emission optical system
19a: needle
19b: needle driving mechanism
20: absorption current detector
21: display device
22: computer
23: input device
33: sample bed
34: column-shaped portion
C: inclined portion
P: sample piece holder
Q: micro sample piece
R: secondary charged particle
S: sample piece
V: sample

1. A charged particle beam device that mills a sample, comprising:
a charged particle beam emission optical system configured to emit a charged particle beam;
a sample stage configured to hold a sample;
a driving mechanism configured to drive the sample stage; and
a computer configured to set a cross-section of the sample in a milling region and control the charged particle beam emission optical system and the driving mechanism when performing slicing on the set milling region,
wherein the computer,
on the basis of information specifying an angle formed by an irradiation surface of the sample and an irradiation axis of the charged particle beam, makes the driving mechanism perform control such that the irradiation surface and the irradiation axis form the angle;
sets irradiation positions such that regions toward which a plurality of charged particle beams emitted in a predetermined direction of the milling region is emitted overlap previously irradiated regions, respectively, when performing slicing on the milling region of the sample; and
controls the charged particle beam emission optical system and the driving mechanism to perform slicing by scanning the milling region with the charged particle beam while maintaining the angle.

2. (canceled)

3. The charged particle beam device of claim 1, wherein the overlap of the regions toward which the plurality of charged particle beams emitted in the predetermined direction is emitted, respectively, is set to 50% or more and 95% or less of a diameter of the charged particle beams.

4. The charged particle beam device of claim 1, wherein the computer sets a time interval for emitting the plurality of charged particle beams to 100 microseconds or less.

5. The charged particle beam device of claim 1, wherein the computer sets an angle formed by the irradiation surface of the sample and the irradiation axis of the charged particle beam to 0.5 degrees or more.

6. The charged particle beam device of claim 1, wherein the computer changes the milling region in the same direction as a milling progress direction of the irradiation surface in the milling region of the sample, and sets a change amount of the milling region to be equal to a milling progress amount of the irradiation surface.

7. The charged particle beam device of of claim 1, wherein the computer sets a change of the milling region to a position where milling regions before and after the change overlap.

8. The charged particle beam device of claim 1, wherein the computer sets a change amount of the milling region to be 50% or more and 95% or less of a diameter of the charged particle beam.

9. The charged particle beam device of claim 1, wherein the computer sets a change amount of the milling region to be equal to intervals of the plurality of charged particle beams.

10. A method for controlling a charged particle beam device that includes a charged particle beam emission optical system configured to emit a charged particle beam, a sample stage configured to hold a sample, a driving mechanism configured to drive the sample stage, a computer configured to set a cross-section of the sample in a milling region of the sample and control the charged particle beam emission optical system and the driving mechanism when performing slicing on the set milling region, the method comprising:
a step in which the computer controls the driving mechanism on the basis of information specifying an angle formed by an irradiation surface of the sample and an irradiation axis of the charged particle beam, thereby setting the angle formed by the irradiation surface and the irradiation axis;
a step in which the computer sets irradiation positions such that regions toward which a plurality of charged particle beams emitted in a predetermined direction of the milling region is emitted overlap previously irradiated regions, respectively, when performing slicing on the milling region of the sample; and
a step in which the computer controls the charged particle beam emission optical system and the driving mechanism to perform slicing by scanning the milling region with the charged particle beam while maintaining the set angle.
